(19) United States
(12) Patent Application Publication
(10) Pub. No.: US 2007/0029643 A1
(43) Pub. Date: Feb. 8, 2007

(54) Methods for nanoscale structures from optical lithography and subsequent lateral growth

(76) Inventors: Mark Alan LaMonte Johnson, Raleigh, NC (US); Douglas William Barlage, Durham, NC (US); John Muth, Cary, NC (US)

Correspondence Address: JENKINS, WILSON, TAYLOR & HUNT, P. A., 3100 TOWER BLVD, SUITE 1200, DURHAM, NC, 27707, US

(21) Appl. No.: 10/550,178

(22) PCT Filed: Mar. 22, 2004
(86) PCT No.: PCT/US04/08725

§ 371 Date: Sep. 21, 2006

Related U.S. Application Data
(60) Provisional application No. 60/456,770, filed on Mar. 21, 2003.
(60) Provisional application No. 60/456,775, filed on Mar. 21, 2003.

(51) Int. Cl. H01L 23/58

(52) U.S. Cl. 257/651; 977/936; 257/E21.4

(57) ABSTRACT

Methods, and structures formed thereby, are disclosed for forming laterally grown structures with nanoscale dimensions from nanoscale arrays which can be patterned from nanoscale lithography. The structures and methods disclosed herein have applications with electronic, photonic, molecular electronic, spintronic, microfluidic or nano-mechanical (NEMS) technologies. The spacing between laterally grown structures can be a nanoscale measurement, for example with a spacing distance which can be approximately 1-50 nm, and more particularly can be from approximately 3-5 nm. This spacing is appropriate for integration of molecular electronic devices. The pitch between posts can be less than the average distance characteristic between dislocation defects for example in GaN (ρ=10¹⁰/cm²→d=0.1 μm) resulting an overall reduction in defect density. Large-scale integration of nanoscale devices can be achieved using lithographic equipment that is orders of magnitude less expensive that that used for advanced lithographic techniques, such as electron beam lithography.

### RELATED APPLICATIONS

This application claims the benefit of U.S. Provisional Patent Applications Ser. Nos. 60/456,775 and 60/456,770, both filed Mar. 21, 2003, the disclosures of which are incorporated by reference in their entireties. This application relates to co-pending U.S. patent application entitled “METHODS AND SYSTEMS FOR SINGLE- OR MULTI-PERIOD EDGE DEFINITION LITHOGRAPHY”, commonly owned and filed on even date herewith, the disclosure of which is incorporated herein by reference in its entirety.

### TECHNICAL FIELD

The present disclosure relates generally to nanoscale lateral epitaxial growth methods and structures. More particularly, the present disclosure relates to methods, and structures formed thereby, for forming laterally grown structures with nanoscale features from nanoscale arrays patterned from sub-micron lithography.

### BACKGROUND ART

In making semiconductor and nanoscale devices, it is often desirable to make features of increasingly small size in a semiconductor or other material. For example, in fabricating semiconductor devices, operational characteristics, such as frequency response, vary inversely with the size of the patterned features that make up each device. Accordingly, semiconductor and nanoscale device fabrication focuses on different ways to make increasingly smaller device features.

A method for fabricating a submicron-scale structure using optical lithography or photolithography is edge definition or spacer gate lithography. Optical lithography is typically a more inexpensive and less tedious fabrication method versus other, more expensive patterning methods such as electron beam lithography, phase shift lithography, x-ray lithography and deep ultraviolet lithography. However, the minimum feature size achievable by optical lithography is on the 0.5 micron scale size range. As such, there is a need to achieve patterned features smaller than that obtained by optical lithography and with the simplicity or unit cost comparable to that of optical lithography. Edge definition lithography is one method capable of achieving sub-micron scale features and utilizing equipment comparable to that used for traditional optical lithography.

There has been great interest in the growth of Group III-Nitrides, including gallium nitride (GaN), aluminum nitride (AlN), indium nitride (InN), aluminum gallium nitride (AlGaN), indium gallium nitride (InGAN) and combinations of these materials. The direct wide bandgap and the chemical stability of III-Nitrides has been beneficial for high-temperature and high-power operated electronic devices, e.g. hetero-junction bipolar and field effect transistors. GaN or heterostructures containing GaN or its related III-Nitride compounds in particular is a wide bandgap (3.4 eV) semiconductor and has being widely investigated for electronic devices featuring a linear micron dimensional scale, including but not limited to transistors, field emitters and optoelectronic devices, such as light emitting diodes (LEDs), laser diodes, and photo detectors which operate in the green, blue or ultraviolet (UV) spectral range.

A major problem that has typically been associated with the fabrication of GaN-based microelectronic devices is the threading dislocations or dislocation defects that can be formed in GaN due to differences in lattice constants and differences in the coefficients of thermal expansion between GaN III-Nitride and its substrate (lattice mismatch). Due to the lack of a practical III-Nitride bulk substrate material, III-Nitride material is currently synthesized as a thin film crystalline material upon a non III-Nitride substrate material such as sapphire, silicon carbide, lithium gallate, or silicon. The dislocations originate in the general area of the III-Nitride-substrate interface and can have adverse effects on the electronic or optical properties of devices fabricated on or containing III-Nitride semiconductor materials. When III-Nitride is directly grown on a sapphire or another non-III-Nitride substrate, the growth mode may be three-dimensional due to the large lattice mismatch, the chemical dissimilarity, and the thermal expansion difference. A nucleation buffer layer, such as gallium nitride deposited at substantially lower temperature to promote two-dimensional growth or wetting, may often be deposited directly upon the substrate to minimize the three-dimensional growth. The layer can also contain structural defects such as point defects, misfit dislocations, and stacking faults.

Semiconductor material research has strived to discover methods for growing high-quality epitaxial layers on a substrate regardless of the degree of lattice mismatch. Lateral overgrowth, or lateral epitaxial overgrowth (LEO), of III-Nitride has attracted attention in the fabrication of optical and electrical devices with high performance. LEO developed as a selective-area growth technique to reduce dislocation defects in epitaxial layers and is performed by regrowing III-Nitride across a periodic array of stripes or trenches with a 1-20 micron feature scale. A three to four order of magnitude reduction in dislocation density has been routinely achieved in fully coalesced, laterally overgrown III-Nitride semiconductors due to a combination of the dislocation geometry in the wurtzite crystal structure of gallium nitride and the minimized strain matching required for growth on the lateral facet of these structures. LEO has been a key enabling technology for achieving long lifetime blue laser diodes based on GaN/InGaN heterostructures.

During LEO, growth can be performed with or without a mask. Without utilizing a mask, the lateral overgrowth can be accomplished by appropriately controlling the growth conditions. For deposition without a mask, lateral growth is achieved over a trench in the substrate or a trench in the substrate-III-Nitride combined structure. These processes are referred to as cantilever beam epitaxy or pendeoepritaxy. The trench acts as a pseudomask and is fabricated along the same general lateral dimensions as a mask that the trench can replace. The use of the trench or a mask can be dictated by the lateral growth tilt or residual strain requirements of the subsequently laterally overgrown III-Nitride layers. For example, growth perpendicular to a specific crystal plane can be controlled by changing the substrate temperature. In general, at higher III-Nitride synthesis temperatures of 1100° C., lateral growth occurs along planes perpendicular to the substrate surface. At lower synthesis temperatures, below 1040° C., the growth planes tend to form pyramidal planes inclined in relation to the substrate. On a partially masked GaN seed layer, the GaN layer grows vertically through windows in the mask and then laterally over the masked area. The mask can prevent dislocation defects from propagating vertically such that the laterally grown portions can be nearly defect-free even despite high density of dislocations present in the underlying substrate. Lateral overgrowth can also be accomplished without a mask as mentioned above by appropriately controlling the growth conditions. For example, growth on a mesa or post on a substrate can occur perpendicular to the top of the post and also from the sides of the post without any further photolithographic mask steps. While the growth on top of the post will have dislocations, the lateral growth will have very few dislocation defects. Continued reduction and even elimination of dislocation defects is therefore desirable to allow the production of high-performance microelectronic or photonic devices.

While lateral growth has produced significant results in improved crystal quality, lateral growth has not been applied to fabricating three-dimensional active layers or interconnect layers in devices. As lateral overgrowth has only been applied to the problem of reducing defects in III-Nitride semiconductor materials during synthesis, there is the opportunity to apply the lateral overgrowth of III-Nitride materials to the fabrication of structures contained within or interfaced with electronic, photonic or other microscale and nanoscale devices.

Molecular electronics involves the use of molecules, typically organic molecules, as active layer elements for two-terminal and three-terminal devices in digital electronics. The length of these molecules is controlled by chemical design, but is typically 2-5 nanometers (nm) in length. There is the potential for small circuit element features (beyond the limit of silicon CMOS devices) using molecular device elements. As such, there exists a tremendous driving force for molecular electronic technologies to meet the demands of high-density integrated circuit devices. In addition to small feature sizes, molecular electronics depends upon interconnect technology being capable of addressing molecular circuit elements on the 2-5 nm feature size and parallel fabrication technology being capable of supporting ˜10¹¹ molecular device elements across a 1 cm² chip area (<100 nm device pitch) in a controllable manner. As such there is a need to develop structures with nanoscale dimensions which are controllably fabricated as interconnects for molecular electronic device elements. Preferably, such a structure would contain openings of 2-5 nm, a dimension that would be appropriate for insertion of the molecular electronic chemical device elements. Such an interconnect structure would be appropriate for use in conjunction with other nanoscale devices such as carbon nanotubes.

### SUMMARY

The present subject matter discloses methods, and structures formed thereby, for forming laterally grown structures with nanoscale dimensions from nanoscale arrays which can be patterned from any suitable technique, such as for example, optical or other micron-scale and nanoscale lithography methods. The structures and methods disclosed herein have applications with electronic, photonic, molecular electronic, spintronic, microfluidic or nano-electromechanical (NEMS) technologies. A wide bandgap semiconductor material can be used such as gallium nitride and its alloys, for example aluminum gallium nitride, indium gallium nitride and aluminum indium gallium nitride.

Periodic arrays with nanoscale features can therefore be formed in a substrate using a nanoscale lithography technique, such as edge definition lithography. Mesas or posts formed thereby can have a pitch of approximately 5-100 nm, and more particularly approximately 30-50 nm. The posts can be laterally overgrown to result in structures featuring sub-micron or nanoscale dimensions. The spacing between the laterally overgrown portions can be a nanoscale opening, for example with a spacing distance between adjacently grown lateral growth fronts which can be approximately 1-50 nm, and more particularly can be from approximately 3-5 nm, a spacing of nanoscale dimension appropriate for interconnection or integration of molecular electronic device elements. Using this technology, large-scale integration of nanoscale devices can be achieved using lithographic equipment that is orders of magnitude less expensive that that used for competing advanced lithographic techniques, such as electron beam lithography. The nanoscale patterning, growth and fabrication of multi-terminal interconnect nodes disclosed therefore have particular use in association with molecular electronics for device element attachment as the formation of mesas or posts is of a dimension less than the average distance characteristic between dislocation defects for example in GaN (ρ=10¹⁰/cm²d→0.1 μm). Alternatively, the lateral overgrowth may proceed to complete coalescence leaving no gap between adjacent lateral growth fronts.

As the lateral growth periodicity is less than the average spacing between defects, a general reduction in defect density may be expected over the III-Nitride surface fabricated in this manner. The nanoscale patterning of features and subsequent lateral overgrowth have use as a technique to achieve III-Nitride semiconductor materials of reduced dislocation or defect density. Layers fabricated in this method may be used in association with electronic or photonic devices benefiting from low defect densities such as LEDs, laser diodes, photo detectors or transistors.

Accordingly, it is an object to provide novel methods, and structures formed thereby, for forming laterally grown structures with nanoscale dimensions from nanoscale arrays patterned from edge defined lithography or another nanoscale lithographic method.

An object having been stated hereinabove, and which is achieved in whole or in part by the present subject matter, other objects will become evident as the description proceeds when taken in connection with the accompanying drawings as best described hereinbelow.

### BRIEF DESCRIPTION OF THE DRAWINGS

Preferred embodiments of the presently disclosed subject matter will now be explained with reference to the accompanying drawings, of which:

FIG. 1 is a perspective view of an array having posts and trenches with nanoscale dimensions;

FIG. 2 is a cross sectional view of a portion of an array as shown in FIG. 1 of the drawings;

FIG. 3A is a cross sectional view of the array illustrating lateral portions grown from the posts;

FIG. 3B is a cross sectional view of the array illustrating lateral portions grown from the posts with molecular devices attached between the posts;

FIG. 4A is a cross sectional view of the array illustrating lateral overgrowth from the posts without pointed lateral tips;

FIG. 4B is a cross sectional view of the array illustrating lateral portions grown from the posts without pointed lateral tips and with molecular devices attached between the posts;

FIG. 5 is a cross sectional view of the array portion illustrating the lateral portions grown from the posts where the lateral portions have grown together to coalesce;

FIG. 6 is an illustration of a laterally overgrown, three-dimensional, hexagonal pyramidal array;

FIG. 7 is an illustration of a two-terminal configuration for molecular electronics; and

FIG. 8 is an illustration of a three-terminal configuration for molecular electronics.

### DETAILED DESCRIPTION

The present subject matter discloses methods, and structures formed thereby, for forming laterally grown structures with nanoscale dimensions from nanoscale arrays patterned from nanoscale lithography, such as for example and without limitation, edge defined lithography or another lithography method capable of achieving features of a nanoscale dimensional size. The structures and methods disclosed herein have applications with, for example and without limitation, electronic, photonic, molecular electronic, spintronic, microfluidic or nano-electromechanical (NEMS) technologies.

A wide bandgap semiconductor can be used such as Group III nitrides, particularly gallium nitride (GaN). As used herein and appreciated by those of skill in the art, GaN includes alloys of GaN such as aluminum nitride, indium nitride, aluminum gallium nitride, indium gallium nitride and aluminum indium gallium nitride. While the description herein often uses GaN as an example of a material suitable for use, it is contemplated as discussed previously that the present disclosure is suitable for other Group III nitride semiconductor films. It can be reasonably expected that other semiconductor materials with the lateral growth properties similar to those of Gallium Nitride may be fabricated into structures described in the present subject matter. It is understood that when an element such as a layer, region or substrate is referred to as being “on” another element, it can be directly on the other element or intervening elements can also be present. It is also understood that “growth” or “overgrowth” as used herein can refer to any suitable growth technique known now or subsequently to those of skill in the art, and can comprise, for example and without limitation, metal-organic chemical vapor deposition (MOCVD), halide vapor phase epitaxy (HVPE), molecular beam epitaxy (MBE) or another similar crystal synthesis technique providing the function of synthesis and formation of semiconductor crystals.

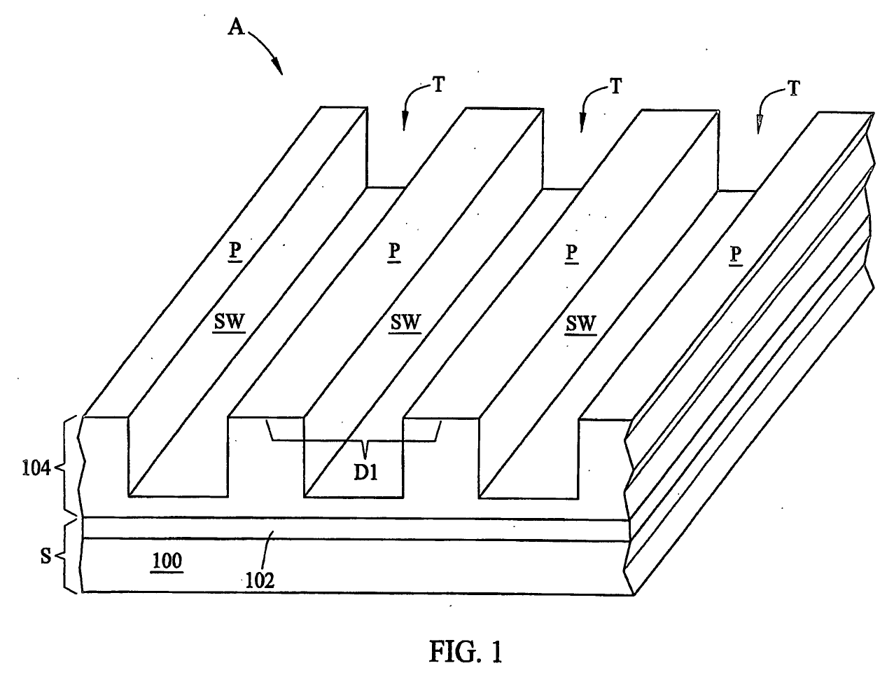

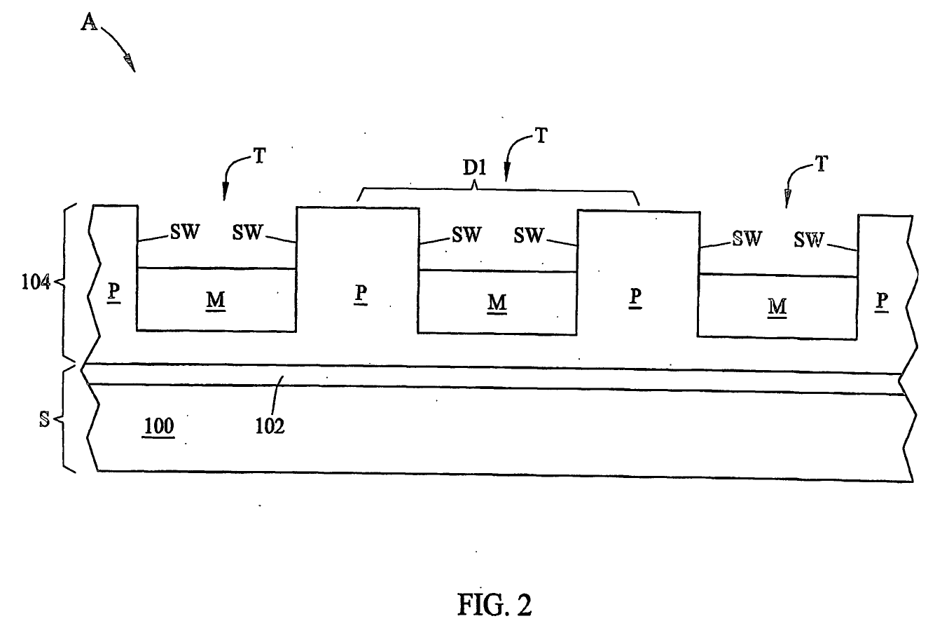

FIGS. 1 and 2 of the drawings illustrate an array, generally designated A, which can be formed using a nanoscale lithography technique, which can be edge definition lithography. As disclosed in greater detail in the commonly assigned, incorporated by reference and co-pending U.S. patent application entitled “METHODS AND SYSTEMS FOR SINGLE- OR MULTI-PERIOD EDGE DEFINITION LITHOGRAPHY”, spacer gate or edge definition lithography can be used to make a periodic array of nanometer-scale features formed by depositing and removing materials from a substrate. Details of the steps involved are disclosed in the co-owned US patent application referenced above. Other types of nanoscale lithographic techniques that could be used to fabricate array A include, for example and without limitation, electron beam lithography, phase-shift lithography, and lithography using a stepper. Substrate S can comprise any suitable composition known to those of skill in the art, such as for example and without limitation silicon, aluminum oxide, aluminum nitride, or silicon carbide. As shown for example in the various figures of drawings, substrate S can comprise a first substrate layer 100 which can be, for example, silicon carbide (6H—SiC(0001)), and a second substrate layer 102 which can be an epitaxial nucleation layer, such as aluminum nitride or GaN for example. Substrate layers 100 and 102 can be of any suitable thickness, such as for example, 0.1 micron (μm) thick. The fabrication of substrate S is well known to those having skill in the art.

Substrate S can include one or more mesas or posts P and channels or trenches generally designated T all defined in an upper layer 104 which can be of any suitable composition known to those of skill in the art. For example and without limitation, layer 104 can comprise any III-Nitride, such as GaN or its alloys. Layer 104 generally has an undesirable and relatively high defect density which, as described previously, can be the result of mismatches in lattice parameters between layer 100, layer 102 and layer 104. These high defect densities can as mentioned previously impact performance of microelectronic or photonic devices formed in layer 104.

Posts P can have a width of approximately 5-100 nm, and more particularly approximately 30-50 nm, and trenches T can have a width of approximately 5-100 nm, and more particularly approximately 30-50 nm such that posts P can be at least approximately 30-50 nm or less apart. Posts P can therefore can have a pitch D1 of approximately 5-100 nm, and more particularly approximately 30-50 nm. As illustrated in FIGS. 1 and 2, array A includes therefore an alternating pattern of nanometer-scale features as posts P are provided having sidewalls SW and trenches T separating posts P. Spaced apart posts P may also be referred to as “mesas”, “pedestals”, “columns”, or other suitable designations which may be used by those of skill in the art. Sidewalls SW may also be referred to as being defined by a plurality of trenches T, which can also be referred to as “wells” in layer 104. Sidewalls SW may also be thought of as being defined by a series of alternating trenches T and posts P. It is understood that sidewalls SW need not be orthogonal in relation to underlying layers, but rather may be oblique thereto. Finally, it will also be understood that although sidewalls SW are shown in cross-section in FIGS. 2-5, posts P and trenches T may define elongated regions that are straight, V-shaped or have other shapes, similar to the elongated features shown in FIG. 1. Trenches T may extend into the layer 102 and even into substrate layer 100. Posts P can be formed with or without using a mask M shown for example in FIG. 2.

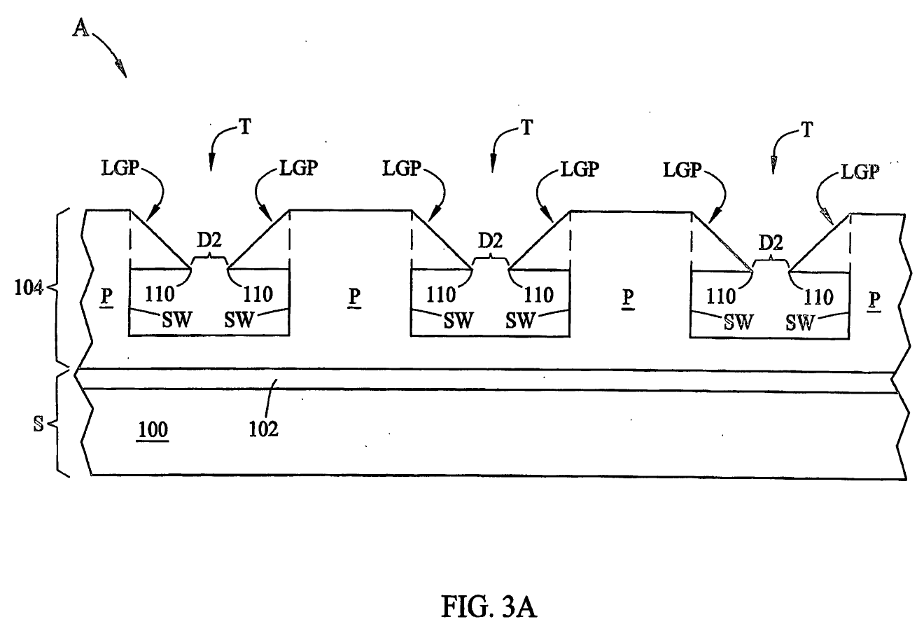

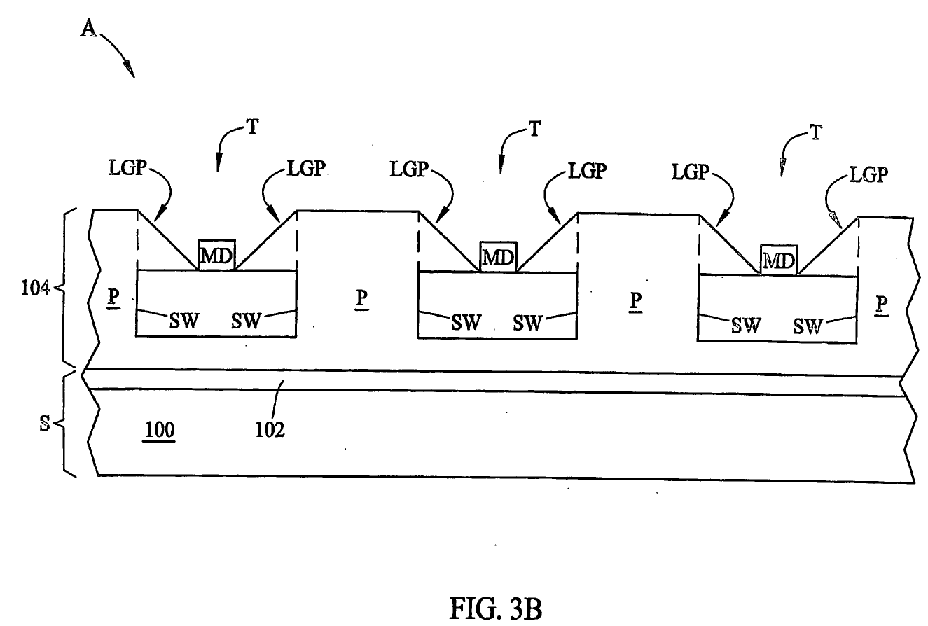

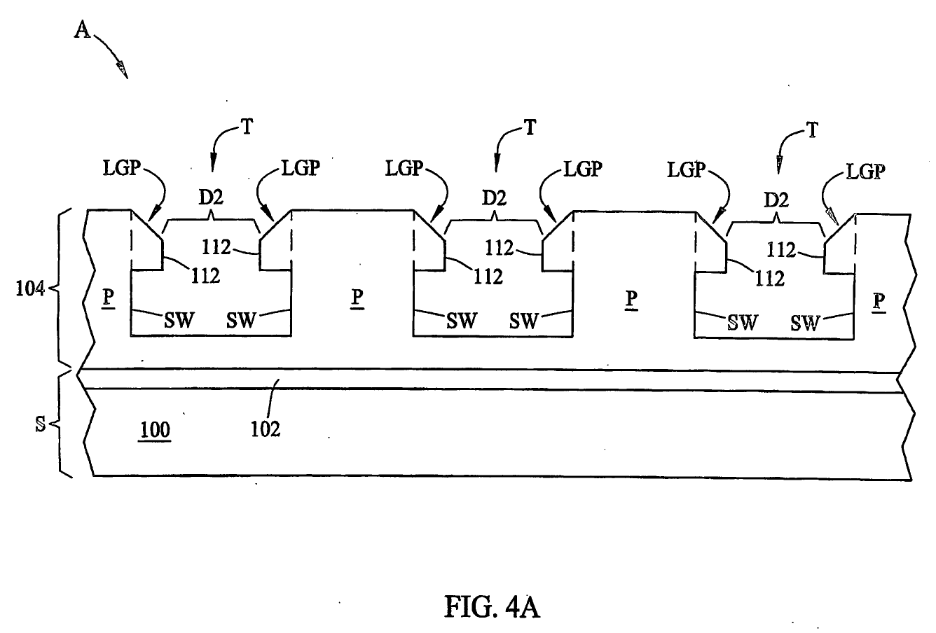

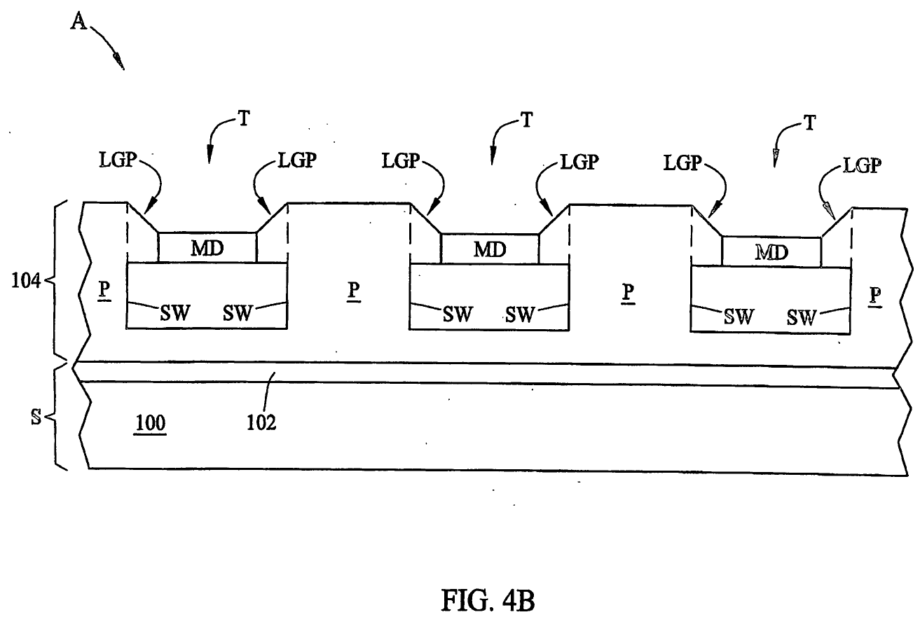

In accordance with the subject matter disclosed herein, post P can be laterally overgrown to form lateral growth portions as described and illustrated, for example, with reference to FIGS. 3A-6 of the drawings. Referring to FIGS. 3A, 3B, 4A and 4B specifically, sidewalls SW of posts P can be laterally grown on both sides of posts P in the direction of other posts P to form lateral growth portions generally designated LGP which grow laterally from the upper portion of each of sidewalls SW. As used herein, the term “lateral” means a direction that is orthogonal to the sidewalls SW and at least generally parallel to the substrate. It will also be understood that some vertical growth on the posts P may also take place during the lateral growth from sidewalls SW. As used herein, the term “vertical” denotes a directional parallel to the sidewalls SW and at least generally perpendicular to the substrate. Control of the growth parameters can result in lateral growth portions LGP having predetermined configurations. For example and as shown in FIGS. 3A and 3B, the lateral growth can be controlled such that lateral growth portions LGP are triangular shaped with pointed lateral fronts 110. As another example and as shown in FIGS. 4A and 4B, the lateral growth can be controlled such that lateral growth portions LGP are only partially triangularly shaped and have flat fronts 112. It is also possible to create conditions where only vertical sidewalls occur on the lateral growth portions. Lateral growth of posts P can extend over and be spaced apart from the bottoms of trenches T. Other suitable shapes can be used for lateral growth portions LGP in accordance with the present disclosure.

In accordance with this disclosure, the growth of lateral growth portions LGP can be advantageously controlled such that the spacing between the lateral growth fronts, such as fronts 110 or 112, can be controlled and predetermined based upon growth conditions utilized. For example, the lateral growth fronts, such as fronts 110 or 112 can be spaced apart at their closest points by spacing distance D2 shown in FIGS. 3A and 4A, which can be approximately 1-50 nm, and more particularly can be from approximately 3-5 nm. A spacing of 1-50 nm between lateral growth fronts, such as fronts 110 or 112, is appropriate for a structure for the subsequent interconnection of nanoscale electronic device elements such as molecular electronic devices. Stopping the growth at the appropriate times permits a gap between lateral growth fronts, distance D2 in FIGS. 3A and 4A, of controllable dimensions to be formed. Molecular electronic devices MD can therefore be attached to and between posts P by connection with the lateral growth fronts, such as fronts 110 or 112, as shown for example in FIGS. 3B and 4B. Molecular electronic devices MD can therefore be formed by insertion in spacing D2 between adjacent growth fronts. Interconnection with the molecular devices is then achieved by connection through appropriate adjacent post P which are in contact with the molecular electronic devices MD. Pitch D1 can be less than the average spacing between dislocation defects in the underlying substrate layers 102 or 100. As such lateral overgrowth can act to mitigate or reduce the density of dislocations over the entire semiconductor surface in the subsequently grown layer 104, and not just in the laterally overgrown region as is observed when the pitch is larger than the spacing between dislocation defects.

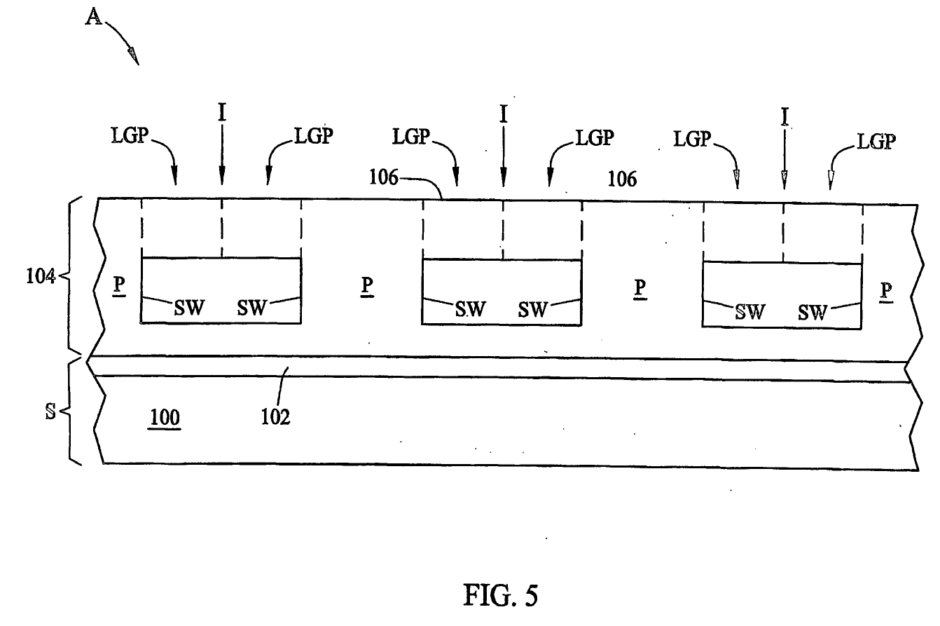

Referring to FIG. 5, lateral growth portions LGP can be allowed to grow laterally until the lateral growth fronts from adjacent posts P coalesce at interfaces I in or above trenches T to form a continuous layer 106 of laterally grown material. The dislocation densities in the underlying layer 104 generally do not propagate laterally from sidewalls SW with the same density as vertically from layer 104. As such, the upper, continuous layer 106 can have a low defect density. Accordingly, layer 106 is a high quality semiconductor material for devices. It will be understood that a mask need not be used for fabrication using lateral growth as described since the lateral growth is directed from sidewalls SW. Appropriate controlling growth parameters and/or appropriately patterning underlying layer 104 can allow for predetermined lateral growth in a desired manner. In general, growth conducted at 1050° C. to more than 100° C. by MOCVD will achieve perpendicular growth fronts which will subsequently coalesce.

As discussed previously, molecular electronics involves the use of organic molecules as active layer elements for two-terminal and three-terminal devices in digital electronics, and these molecules are often 2-5 nm in length. The success of molecular electronics largely depends upon interconnect technology being capable of addressing molecular circuit elements on the 2-5 nm feature size and parallel fabrication technology being capable of supporting ˜10¹¹ molecular elements across a 1 cm² chip area (<100 nm device pitch). As shown in FIGS. 3 and 4 of the drawings and as described above, array A can provide posts P with laterally grown portions LGP of a desirable shape. Posts P with laterally grown portions LGP are illustrated in FIGS. 3A, 3B, 4A and 4B in cross section, and it can be Understood that posts P laterally grown portions LGP can be elongated on array A similar to array A as shown in FIG. 1 before the lateral overgrowth has occurred. Posts P can be defined by conventional photolithography and etching steps using edge defined lithography. In addition, to be elongated posts P can be defined in other geometries that are determined by the desired pattern on the conventional photolithography mask, the orientation of the mask with respect to the crystal orientation of the underlying seed layer, and the method of etching, such as reactive ion etching that can be used to define posts P. Once posts P are defined, the growth conditions such as substrate temperature and gas flow determine the rate at which the preferred crystal planes for growth will laterally grow. In this manner the lateral overgrowth can extend from one post to another if coalescence is desired, or by stopping the growth, a nm scale opening suitable for molecular or other devices can be obtained.

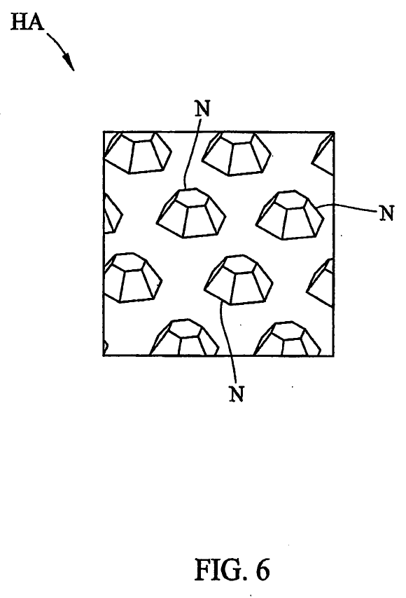

FIG. 6 of the drawings is an illustration of a laterally overgrown, three-dimensional, hexagonal pyramidal array generally designated HA with a plurality of separate and spaced apart, truncated interconnect nodes N. The epitaxially controlled facet preference present on nodes N during lateral growth is illustrated and can be appreciated by those of skill in the art. The dimensions can be controlled for the molecular electronics interconnect array as growth fronts come together, as further described below. While the spacing between lateral nucleation sites is controlled by the limitations of lithography, the gap or opening between uncoalesced growth fronts of nodes N is primarily determined by the lateral growth rate and total growth time. The direction of and rate of lateral growth are determined by reactor parameters such a substrate temperature, gas flow rates and pressures, and the orientation of the original seed layers and posts. The coalescence or opening dimensions can be controlled through ex-situ measurement and adjustment of growth parameters or real time in-situ process monitoring such as optical reflectance. The sub-nanometer degree of spatial variation between nodes N provides a precise gap for molecular interconnection. Furthermore, the shape of the lateral growth front is determined as a low-index crystal plane, with the surface energy (and resulting habit plane preference) determined primarily by substrate temperature during epitaxial regrowth. The lateral regrowth comprises not only preferred sidewall configuration, but also planar and azimuthal facet orientation.

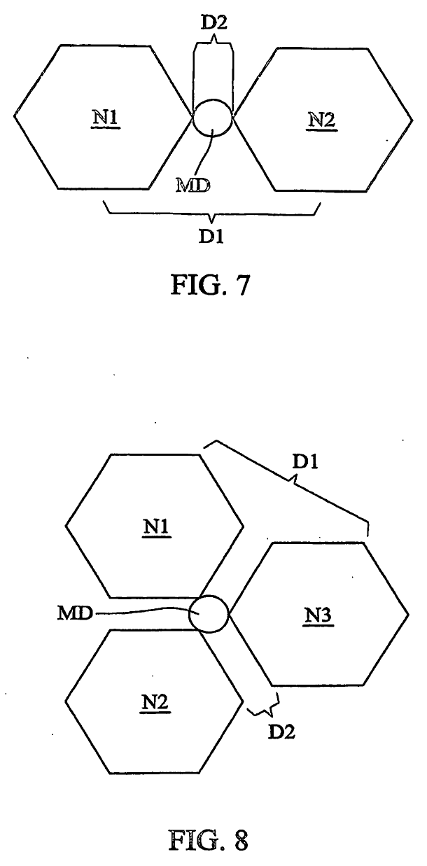

FIG. 7 of the drawings therefore illustrates a two-terminal device such as a diode for molecular electronics wherein interconnect nodes N1 and N2 are spaced apart at their closest points by spacing distance D2, which can be approximately 1-50 nm, and more particularly can be from approximately 3-5 nm. Interconnect nodes N1 and N2 can have a pitch D1 of approximately 5-100 nm, and more particularly approximately 30-50 nm. Molecular device MD is attached between nodes N1 and N2. FIG. 8 of the drawings illustrates a three-terminal device, such as a transistor for molecular electronics wherein interconnect nodes N1, N2 and N3 can be spaced apart at their closest points by spacing distance D2 as in FIG. 7. Similar to FIG. 7, nodes N1, N2 and N3 can have a pitch D1 of approximately 5-100 nm, and more particularly approximately 30-50 nm. Molecular device MD is attached between nodes N1, N2 and N3. The hexagonal feature size enables a cellular approach to circuit and logic design.

The lateral overgrowth procedure can comprise any suitable steps known by those of skill in the art for lateral overgrowth of III-Nitride semiconductor. As an example and without limitation, the lateral overgrowth procedures disclosed in commonly assigned U.S. Pat. Nos. 6,602,763 and 6,608,327 and in commonly assigned and pending U.S. Patent Application No. 2003/0194828 can be utilized and are incorporated by reference in their entireties.

As can be readily appreciated by those of skill in the art therefore, the methods and structures as described herein provide an interconnect technology for molecular electronics to meet the spatial features required. Interconnect nodes are provided for molecular device attachment, and nanoscale patterning and feature control on a nanometer spatial scale is provided. Tailored electron affinity and work function is provided enabling molecular contacts through AlₓGa₁₋ₓN controlled composition control and doping Control over the electron affinity by controlling the alloy composition (composition of lateral growth portions LGP in FIGS. 3A-4B) and doping will result in more efficient electron transfer between the laterally grown defined layers and a given molecular electronic device, since different molecules have different preferred work function and electron affinities for efficient electron transfer. The electron affinity of the laterally grown structures can be controlled between that of GaN and of AlN through adjustments of composition of the laterally overgrown material in contact with a molecular electronic device. The methods described above may be used to form a variety of nanometer-pitched electronic or nano-electro mechanical devices. Examples of devices that may be formed using the above described techniques include heterostructure field effect transistors (FETS), heterojunction bipolarjunction transistors (BJTs), gallium nitride and indium gallium nitride based FETs, gallium arsenide and indium gallium arsenide based FETs, and indium phosphide based FETs.

It will be understood that various details of the subject matter disclosed herein may be changed without departing from the scope of the present disclosure. Furthermore, the foregoing description is for the purpose of illustration only, and not for the purpose of limitation, as the subject matter disclosed herein is defined by the claims as set forth hereinafter.

What is claimed is:

1. A semiconductor structure comprising:
(a) a substrate including at least one post, the post size and spacing having a nanoscale width of approximately 100 nanometers or less; and
(b) a laterally grown portion extending laterally from the post over the substrate.

2. The structure according to claim 1 wherein the post is formed by sub-micron lithography.

3. The structure according to claim 2 wherein the post is formed by edge definition lithography.

4. The structure according to claim 1 wherein the laterally grown portion is spaced vertically from the substrate.

5. The structure according to claim 1 wherein the post has a width of approximately 30 nanometers or less.

6. The structure according to claim 1 wherein the laterally grown portion comprises outermost pointed fronts.

7. The structure according to claim 1 wherein the laterally grown portion comprises outermost flat fronts.

8. The structure according to claim 1 wherein the laterally grown portion comprises an at least generally triangular shape.

9. A semiconductor structure comprising:
(a) a substrate having dislocation defects spaced apart by an average distance characteristic for the substrate;
(b) at least one post included on the substrate, the post having a width less than the average distance separating the dislocation defects characteristic for the substrate; and
(c) a laterally grown portion extending laterally from the post and over the substrate.

10. The structure according to claim 9 wherein the post is formed by sub-micron lithography.

11. The structure according to claim 10 wherein the post is formed by edge definition lithography.

12. The structure according to claim 9 wherein the laterally grown portion is spaced vertically from the substrate.

13. The structure according to claim 9 wherein the post has a width of approximately 30 nanometers or less.

14. The structure according to claim 9 wherein the laterally grown portion comprises outermost pointed fronts.

15. The structure according to claim 9 wherein the laterally grown portion comprises outermost flat fronts.

16. The structure according to claim 9 wherein the laterally grown portion comprises an at least generally triangular shape.

17. A semiconductor structure comprising:
(a) a substrate including a plurality of posts, each post having a nanoscale pitch of approximately 100 nanometers or less; and
(b) each post having a laterally grown portion extending laterally over the substrate, wherein a spacing distance separating the laterally grown portions of the posts is approximately 50 nanometers or less.

18. The structure according to claim 17 wherein the post is formed by sub-micron lithography.

19. The structure according to claim 18 wherein the post is formed by edge definition lithography.

20. The structure according to claim 17 wherein the posts are separated by a spacing distance of approximately 5 nanometers or less.

21. The structure according to claim 17 wherein the posts have a pitch of approximately 30 nanometers or less.

22. The structure according to claim 17 wherein each laterally grown portion comprises outermost pointed fronts.

23. The structure according to claim 17 wherein each laterally grown portion comprises outermost flat fronts.

24. The structure according to claim 17 wherein each laterally grown portion comprises an at least generally triangular shape.

25. The structure according to claim 17 comprising a molecular electronics device attached between the laterally grown portions of the posts.

26. The structure according to claim 17 wherein the laterally grown portions are coalesced to form a layer.

27. The structure according to claim 19 wherein the coalesced layer has reduced dislocation defects.

28. The structure according to claim 17 wherein the posts comprise a plurality of three-dimensional interconnect nodes.

29. The structure according to claim 28 further comprising a molecular electronic device attached between at least two of the interconnect nodes.

30. A semiconductor structure comprising:
(a) a substrate having a dislocation defects spaced apart by an average distance characteristic for the substrate;
(b) a plurality of posts included on the substrate; and
(c) a laterally grown portion extending laterally from each post and over the substrate, wherein a spacing between adjacent laterally growth portions from adjacent posts is less than the average distance separating the dislocation defects characteristic for the substrate.

31. The structure according to claim 30 wherein the post is formed by sub-micron lithography.

32. The structure according to claim 31 wherein the post is formed by edge definition lithography.

33. The structure according to claim 30 wherein the laterally grown portion is spaced vertically from the substrate.

34. The structure according to claim 30 wherein the post has a width of approximately 30 nanometers or less.

35. The structure according to claim 30 wherein the laterally grown portion comprises outermost pointed fronts.

36. The structure according to claim 30 wherein the laterally grown portion comprises outermost flat fronts.

37. The structure according to claim 30 wherein the laterally grown portion comprises an at least generally triangular shape.

38. A semiconductor structure comprising:
(a) a substrate including a plurality of posts, each post having a nanoscale pitch of approximately 100 nanometers or less; and
(b) each post having a laterally grown portion extending laterally over the substrate, wherein the laterally grown portions extend and coalesce to form a coalesced layer.

39. The structure according to claim 30 wherein each post is formed by sub-micron lithography.

40. The structure according to claim 31 wherein the post is formed by edge definition lithography.

41. The structure according to claim 30 wherein the coalesced layer has reduced dislocation defects.

42. A method for forming a laterally grown semiconductor structure comprising:
(a) forming at least one post on a substrate, the post having a nanoscale width of approximately 100 nanometers or less; and
(b) growing a laterally grown portion from the post extending laterally from the post over the substrate.

43. The method according to claim 42 comprising growing the post by sub-micron lithography.

44. The method according to claim 43 comprising growing the post by edge definition lithography.

45. The method according to claim 43 comprising growing the laterally grown portion to be spaced vertically from the substrate.

46. The method according to claim 42 wherein the post has a width of approximately 100 nanometers or less.

47. The method according to claim 42 comprising growing the laterally grown portion wherein the laterally grown portion comprises outermost pointed fronts.

48. The method according to claim 42 comprising growing the laterally grown portion structure wherein the laterally grown portion comprises outermost flat fronts.

49. The method according to claim 42 comprising growing the laterally grown portion structure wherein the laterally grown portion comprises an at least generally triangular shape.

50. A method for forming a laterally grown semiconductor structure comprising:
(a) providing a substrate having dislocation defects spaced apart by an average distance characteristic for the substrate;
(b) forming at least one post on the substrate, the post having a width less than the average distance separating the dislocation defects characteristic for the substrate; and
(c) growing a laterally grown portion from the post extending laterally from the post and over the substrate.

51. The method according to claim 50 comprising growing the post by sub-micron lithography.

52. The method according to claim 50 comprising growing the post by edge definition lithography.

53. The method according to claim 50 comprising growing the laterally grown portion to be spaced vertically from the substrate.

54. The method according to claim 50 wherein the post has a width of approximately 100 nanometers or less.

55. The method according to claim 50 comprising growing the laterally grown portion wherein the laterally grown portion comprises outermost pointed fronts.

56. The method according to claim 50 comprising growing the laterally grown portion structure wherein the laterally grown portion comprises outermost flat fronts.

57. The method according to claim 50 comprising growing the laterally grown portion structure wherein the laterally grown portion comprises an at least generally triangular shape.

58. A method for forming a laterally grown semiconductor structure comprising:
(a) forming a plurality of posts on a substrate, each post having a nanoscale width of approximately 100 nanometers or less; and
(b) growing a laterally grown portion from each of the posts extending laterally over the substrate, wherein a spacing distance separating the laterally grown portions of the posts is approximately 50 nanometers or less.

59. The method according to claim 58 wherein each post is formed by sub-micron lithography.

60. The method according to claim 59 wherein each post is formed by edge definition lithography.

61. The method according to claim 58 comprising growing each laterally grown portion to be spaced vertically from the substrate.

62. The method according to claim 58 wherein each post has a width of approximately 100 nanometers or less.

63. The method according to claim 58 comprising growing each laterally grown portion wherein the laterally grown portion comprises outermost pointed fronts.

64. The method according to claim 58 comprising growing each laterally grown portion structure wherein the laterally grown portion comprises outermost flat fronts.

65. The method according to claim 58 comprising growing each laterally grown portion structure wherein the laterally grown portion comprises an at least generally triangular shape.

66. The method according to claim 58 comprising attaching a molecular electronic device to and between adjacent laterally grown portions of adjacent posts.

67. The method according to claim 58 comprising forming a plurality of three dimensional interconnect nodes for molecular device attachment from the laterally grown posts.

68. The method according to claim 67 comprising attaching a molecular electronic device to and between adjacent laterally grown portions of adjacent posts.

69. A method of controlling electron affinity in a laterally overgrown semiconductor structure, comprising:
(a) providing a substrate with a plurality of posts included on the substrate, each post having laterally overgrown portions and wherein the laterally overgrown portions of adjacent posts are spaced apart a nanoscale dimension;
(b) interconnecting a molecular electronic device between and to the laterally overgrown portions of adjacent posts; and
(c) controlling composition of the laterally overgrown portions to control electron affinity between the laterally overgrown portions and the molecular electronics device.
